(19) United States
(12) Patent Application Publication
(10) Pub. No.: US 2014/0301040 A1
(43) Pub. Date: Oct. 9, 2014

(54) VIDEO SURVEILLANCE MODULE WITH HEAT-DISSIPATING FUNCTION

(71) Applicant: Chi-Hung Hsiao, New Taipei City (TW)

(72) Inventor: Chi-Hung Hsiao, New Taipei City (TW)

(21) Appl. No.: 13/563,723

(22) Filed: Jul. 31, 2012

(30) Foreign Application Priority Data
Aug. 2, 2011 (TW) 100127393

(51) Int. Cl. H05K 7/20

(52) U.S. Cl. CPC H05K 7/20154
USPC 361/697

(57) ABSTRACT

A video surveillance module with a heat-dissipating function includes a thermal conductive casing, a transparent cover, a video capturing device, a motherboard device, and a first fan. The transparent cover is connected to the thermal conductive casing. The video capturing device is disposed in the transparent cover. The motherboard device is disposed in the thermal conductive casing and electrically connected to the video capturing device. The first fan is disposed on the motherboard device and opposite to the thermal conductive casing for generating a first airflow. The first fan guides the first airflow toward the thermal conductive casing.

### BACKGROUND OF THE INVENTION

1. Field of the Invention

The present invention relates to a video surveillance module, and more specifically, to a video surveillance module with a heat-dissipating function.

2. Description of the Prior Art

In general, a video surveillance module is mainly applied to outdoor video capturing. That is, the video surveillance module is usually operated in an environment having a wide temperature variation range (about −40° C. to 50° C.). Thus, there are usually a heating device and a heat-dissipating device installed in the video surveillance module. A common design involves disposing a heating device on major components (e.g. a motherboard, a video-capturing control board, and a power control board) in the video surveillance module and disposing a heat-dissipating fan above the major components. In such a manner, when the video surveillance module cannot work properly due to a low temperature, the video surveillance module could activate the heating device to heat the major components until the major components are heated to their working temperature (about −10° C.). On the other hand, when the video surveillance module is working in an environment with a high temperature, the video surveillance module could activate the heat-dissipating fan to guide airflow toward the major components for decreasing the internal temperature of the video surveillance module, so as to prevent crash or malfunction of the major components.

However, the video surveillance module would be heated locally in the aforesaid design since the aforesaid design lacks a preferable heat exchange mechanism and an appropriate airflow guiding design. Thus, the video surveillance module could not be heated to its working temperature quickly when the temperature around the video surveillance module is too low. In addition, heat energy generated by the video surveillance module could not be dissipated efficiently when the temperature around the video surveillance module is too high.

### SUMMARY OF THE INVENTION

The present invention provides a video surveillance module with a heat-dissipating function. The video surveillance module includes a thermal conductive casing, a transparent cover, a video capturing device, a motherboard device, and a first fan. The transparent cover is connected to the thermal conductive casing. The video capturing device is disposed in the transparent cover. The motherboard device is disposed in the thermal conductive casing and electrically connected to the video capturing device. The first fan is disposed on the motherboard device and opposite to the thermal conductive casing for generating a first airflow. The first fan guides the first airflow toward the thermal conductive casing.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an external diagram of a video surveillance module according to an embodiment of the present invention.

FIG. 2 is an internal diagram of the video surveillance module in FIG. 1.

FIG. 3 is a diagram of a motherboard device in FIG. 2.

### DETAILED DESCRIPTION

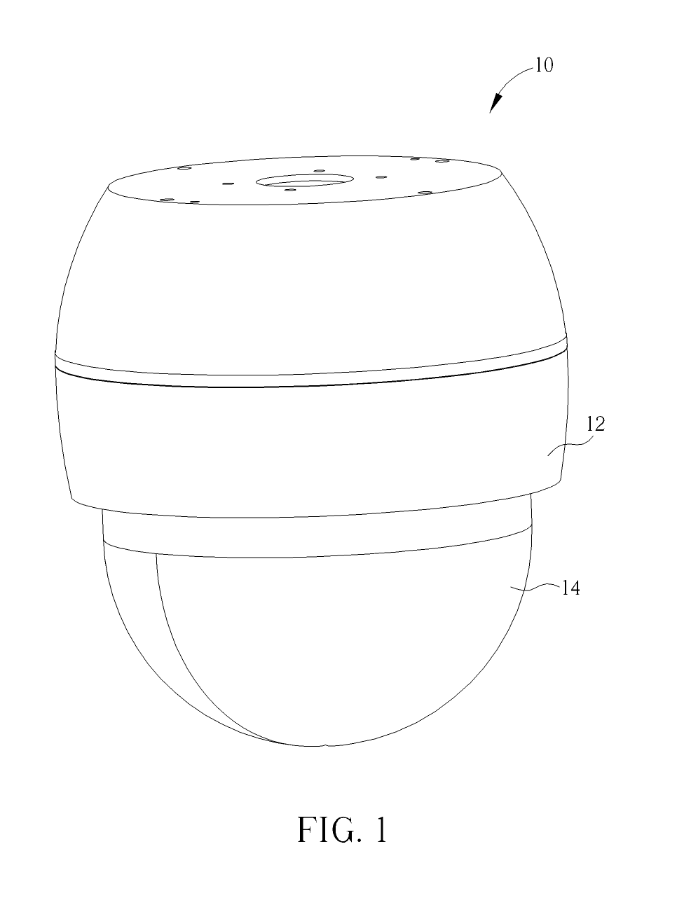

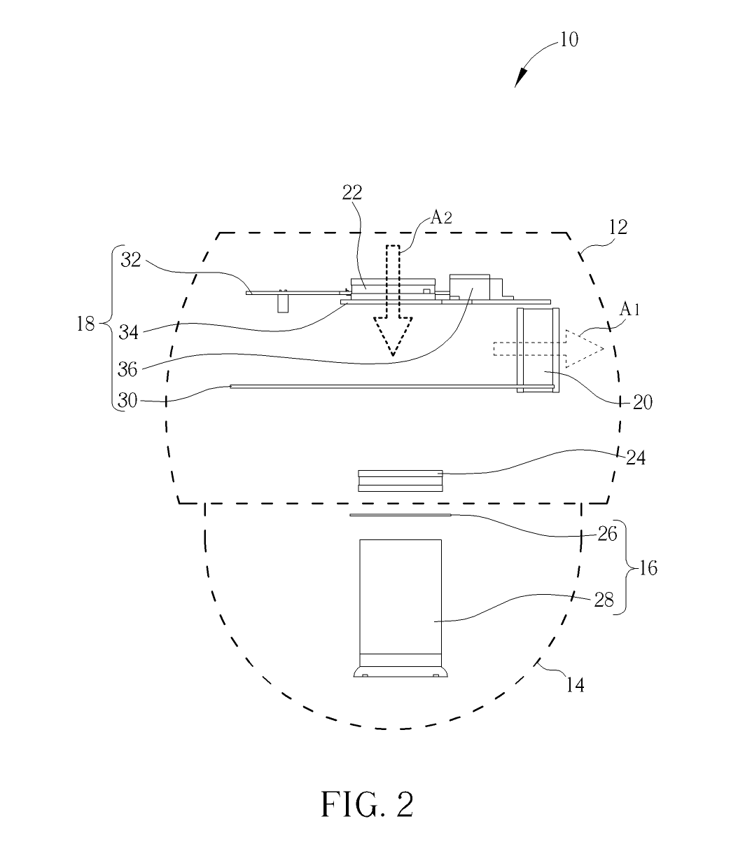

Please refer to FIG. 1 and FIG. 2. FIG. 1 is an external diagram of a video surveillance module 10 according to an embodiment of the present invention. FIG. 2 is an internal diagram of the video surveillance module 10 in FIG. 1. As shown in FIG. 1 and FIG. 2, the video surveillance module 10 includes a thermal conductive casing 12, a transparent cover 14, an video capturing device 16, a motherboard device 18, a first fan 20, a second fan 22, and a third fan 24. The thermal conductive casing 12 is preferably made of metal material for rapid heat conduction. The transparent cover 14 is connected to the thermal conductive casing 12. The video capturing device 16 is disposed in the transparent cover 14 so that the video capturing device 16 can capture images under protection of the transparent cover 14. The video capturing device 16 can include a video-capturing control board 26 and a lens set 28. The video-capturing control board 26 is used for controlling operations of the lens set 28, such as image capturing or image signal transmission. The lens set 28 is electrically connected to the video-capturing control board 26 for capturing image outside the transparent cover 14. The operational control between the video-capturing control board 26 and the lens set 28 and the related designs are commonly seen in the prior art, and the related description is omitted herein.

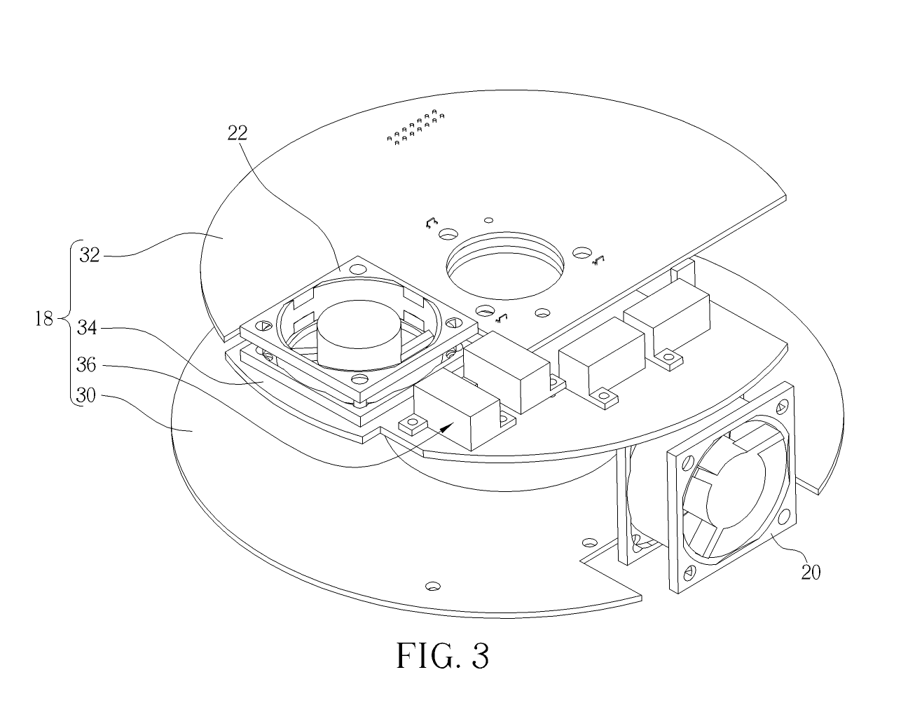

More detailed description for the dispositions and designs of the motherboard device 18, the first fan 20, the second fan 22, and the third fan 24 is provided as follows. Please refer to FIG. 3, which is a diagram of the motherboard device 18 in FIG. 2. As shown in FIG. 3, the motherboard device 18 is disposed in the thermal conductive casing 12 and electrically connected to the video capturing device 16. The motherboard device 18 includes a motherboard 30, a power control board 32, at least one thermal conductive sheet 34 (one shown in FIG. 1, but not limited thereto), and a heating device 36. The power control board 32 is electrically connected to and disposed above the motherboard 30 for providing the video surveillance module 10 with sufficient power. In this embodiment, the thermal conductive sheet 34 is disposed on the power control board 32. The thermal conductive sheet 34 is preferably made of material with a high thermal conductive coefficient, such as metal. The heating device 36 is disposed on the thermal conductive sheet 34 for heating the thermal conductive sheet 34. In other words, via the design in which the heating device 36 is disposed on the thermal conductive sheet 34, heat energy generated by the heating device 36 could be transmitted quickly by the thermal conductive sheet 34.

Next, please refer to FIG. 2. The first fan 20 is disposed on the motherboard 30 and opposite to the thermal conductive casing 12. The first fan 20 is used for guiding a first airflow A₁ toward the thermal conductive casing 12. The second fan 22 is disposed on the thermal conductive sheet 34 and located at a side of the heating device 36. The second fan 22 is used for guiding a second airflow A₂ to pass through the thermal conductive sheet 34 and the motherboard 30 and then flow toward the first fan 20. The flowing direction of the first airflow A₁ corresponds to the airflow direction of the first fan 20, meaning that the first airflow A₁ is substantially parallel to the motherboard 30. The flowing direction of the second airflow A₂ corresponds to the airflow direction of the second fan 22, meaning that the second airflow A₂ is substantially perpendicular to the motherboard 30. Furthermore, the third fan 24 is disposed between the video-capturing control board 26 and the motherboard 30 for guiding the first airflow A₁ toward the video-capturing control board 26 after the first airflow A₁ passes through the thermal conductive casing 12.

The heat dissipating design and the heating design of the video surveillance module 10 are described in details herein. Please refer to FIG. 2 and FIG. 3. When the video surveillance module 10 is in an environment with an excessive high temperature (e.g. greater than 50° C.), the video surveillance module 10 utilizes the motherboard 30 to activate the first fan 20, the second fan 22, and the third fan 24. At this time, the second airflow A₂ generated by the second fan 22 and the first airflow A₁ generated by the first fan 20 can cooperatively take away heat energy generated during the power control board 32 and the motherboard 30 are working, so as to achieve the heat dissipating purpose. Subsequently, via the disposition of the first fan 20 being opposite to the thermal conductive casing 12, the first airflow A₁ can flow toward the thermal conductive casing 12 in a face-to-face manner so as to form an impinging airflow toward the thermal conductive casing 12. Thus, a preferable heat exchange mechanism could be established accordingly, so that heat energy taken by the second airflow A₂ and the first airflow A₁ could be efficiently dissipated to the outer environment via the thermal conductive casing 12. Furthermore, the first airflow A₁ could be guided to flow downward after impinging on the thermal conductive casing 12. At this time, since the third fan 24 is disposed between the video-capturing control board 26 and the motherboard 30 and the first airflow A₁ is transformed into a cold airflow after the heat exchange process of the first airflow A₁ with the thermal conductive casing 12 is performed, the third fan 24 could guide the first airflow A₁ to flow toward the video-capturing control board 26, and then heat energy generated by the video-capturing control board 26 could be dissipated by the first airflow A₁.

In such a manner, via the airflow guiding designs of the first fan 20, the second fan 22, and the third fan 24 and the disposition of the first fan 20 being opposite to the thermal conductive casing (as shown in FIG. 2), the video surveillance module 10 could efficiently dissipate heat energy generated by the video-capturing control board 26, the motherboard 30, and the power control board 32 to the outer environment via the thermal conductive casing 12 when the video surveillance module 10 is in an environment with an excessively-high temperature. Accordingly, the internal temperature of the video surveillance module 10 could be reduced, so as to prevent crash or malfunction of the video surveillance module 10 due to the excessively-high temperature.

On the other hand, when the video surveillance module 10 is in an environment with an excessively-low temperature (e.g. lower than −10° C.), the video surveillance module 10 could utilize the motherboard 30 to activate the first fan 20, the second fan 22, the third fan 24, and the heating device 36. Subsequently, heat energy generated by the heating device 36 could be efficiently transmitted to the power control board 32 via the thermal conductive sheet 34 so as to heat the power control board 32 to its working temperature (e.g. greater than −10° C.). Accordingly, the power control board 32 could be activated properly for providing power to the major components (e.g. the video capturing device 16 and the motherboard device 18) of the video surveillance module 10.

Furthermore, via the disposition of the second fan 22 on the thermal conductive sheet 34, the heat energy generated by the heating device 36 could be taken away by the second airflow A₂ and then transmitted to the motherboard 30 via guidance of the second fan 22 to increase the temperature of the motherboard 30, so that the motherboard 30 could be activated properly. Besides, since the first fan 20 is disposed on the motherboard 30 and opposite to the thermal conductive casing 12, the heat energy generated by the heating device 36 could be further taken away by the first airflow A₁ via guidance of the first fan 20 after being transmitted to the motherboard 30. Subsequently, the first airflow A₁ could flow toward the thermal conductive casing 12 to form an impinging airflow toward the thermal conductive casing 12, so as to establish a preferable heat exchange mechanism. Accordingly, the temperature of the thermal conductive casing 12 could be increased quickly so as to increase the internal temperature of the video surveillance module 10.

In addition, since the first airflow A₁ could be guided to flow downward after impinging on the thermal conductive casing 12 and the third fan 24 is disposed between the video-capturing control board 26 and the motherboard 30, the third fan 24 could guide the first airflow A₁ to flow toward the video-capturing control board 26, so as to heat the video-capturing control board 26 to its working temperature.

In such a manner, via the designs of the heating device 36 being disposed on the thermal conductive sheet 34 and the first fan 20 is opposite to the thermal conductive casing 12 and the airflow guiding designs of the first fan 20, the second fan 22, and the third fan 24 (as shown in FIG. 2), the video surveillance module 10 could quickly transmit the heat energy generated by the heating device 36 to the power control board 32, the motherboard 30, and the video-capturing control board 26 when the video surveillance module 10 is in an environment with an excessively-low temperature, so as to increase the internal temperature of the video surveillance module 10. Accordingly, the problem that the major components in the video surveillance module 10 cannot work properly due to the excessively-low temperature could be solved.

It should be mentioned that assembly of the second fan 22, the thermal conductive sheet 34, and the heating device 36 is not limited to the aforesaid embodiment, but depends on the heat dissipating needs of the video surveillance module 10. That is, all designs of utilizing assembly of the second fan 22, the thermal conductive sheet 34 and the heating device 36 to transmit the heat energy generated by the heating device 36 to the thermal conductive sheet 34 and the motherboard 30 maybe within the scope of the present invention. For example, the thermal conductive sheet 34 could be disposed on the motherboard 30 instead, and the second fan 22 could be directly disposed above the heating device 36; otherwise, the thermal conductive sheet 34 could be disposed on the motherboard 30 and the power control board 32 respectively, and the second fan 22 could be disposed above the heating device 36 and/or located at the thermal conductive sheet 34 on the power control board 32.

Furthermore, the second fan 22 and the third fan 24 could be omissible for simplifying the structural design of the video surveillance module 10. That is, the video surveillance module 10 could only utilize the design in which the first fan 20 is opposite to the thermal conductive casing 12 for achieve the heating and heat dissipating purposes.

Besides, in practical application, the power control board 32 could be integrated into the motherboard 30 instead, so that number of the boards in the video surveillance module 10 could be reduced from three to two for simplifying the heating and heat dissipating designs of the video surveillance module 10. In this design, the thermal conductive sheet 34 could be disposed on the motherboard 30 instead.

To be noted, the structural design of the video surveillance module 10 should vary correspondingly with different temperature conditions. For example, if the video surveillance module 10 is in an environment with a temperature (e.g. greater than −10° C.) greater than the working temperatures of the major components disposed therein, disposal of the thermal conductive sheet 34 and the heating device 36 could be omitted in the video surveillance module 10; otherwise, if the video surveillance module 10 is in an environment with a temperature (e.g. less than 30° C.) which is not too high for the video capturing device 16, disposal of the third fan 24 could be omitted in the video surveillance module 10. As for other derivative disposal variations, they could be reasoned by analogy and the related description is therefore omitted herein.

Compared with the prior art, the present invention utilizes the design in which the fan is opposite to the thermal conductive casing, to establish an efficient heat exchange mechanism in the video surveillance module by utilizing the airflow guided by the fan to form an impinging airflow toward the thermal conductive casing. Accordingly, not only could the video surveillance module provided by the present invention be heated to its working temperature quickly when the temperature around the video surveillance module is too low, but also reduce the internal temperature of the video surveillance module efficiently for preventing crash or malfunction of the major components in the video surveillance module. Furthermore, via the airflow guiding designs of the first fan, the second fan, and the third fan, the video surveillance module could dissipate the heat energy generated by the video-capturing control board, the motherboard, and the power control board to the outer environment via the thermal conductive casing and transmit the heat energy generated by the heating device to the power control board, the motherboard, and the video-capturing control board quickly. In such a manner, no matter the video surveillance module is in an environment with a high or low temperature, the present invention ensures that the video surveillance module could work properly, so as to improve the operation stability of the video surveillance module.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A video surveillance module with a heat-dissipating function, the video surveillance module comprising:
a thermal conductive casing;
a transparent cover connected to the thermal conductive casing;
a video capturing device disposed in the transparent cover;
a motherboard device disposed in the thermal conductive casing and electrically connected to the video capturing device; and
a first fan disposed on the motherboard device and opposite to the thermal conductive casing for generating a first airflow, the first fan guiding the first airflow toward the thermal conductive casing.

2. The video surveillance module of claim 1, wherein the motherboard device comprises:
a motherboard;
a power control board electrically connected to the motherboard and disposed above the motherboard;
at least one thermal conductive sheet disposed on at least one of the power control board and the motherboard; and
a heating device disposed on the thermal conductive sheet for heating the thermal conductive sheet.

3. The video surveillance module of claim 2, wherein the thermal conductive sheet is disposed on the power control board, and the video surveillance module further comprises:
a second fan disposed on the thermal conductive sheet and located at a side of the heating device for generating a second airflow, the second fan guiding the second airflow to pass through the thermal conductive sheet and the motherboard.

4. The video surveillance module of claim 3, wherein the first airflow is substantially parallel to the motherboard, and the second airflow is substantially perpendicular to the motherboard.

5. The video surveillance module of claim 2, wherein the thermal conductive sheet is disposed on the motherboard, and the video surveillance module further comprises:
a second fan disposed above the heating device for generating a second airflow, the second fan guiding the second airflow to pass through the thermal conductive sheet and the motherboard.

6. The video surveillance module of claim 5, wherein the first airflow is substantially parallel to the motherboard, and the second airflow is substantially perpendicular to the motherboard.

7. The video surveillance module of claim 1, wherein the video capturing device comprises a video-capturing control board, and the video surveillance module further comprises:
a third fan disposed between the video-capturing control board and the motherboard for guiding the first airflow toward the video-capturing control board.

8. The video surveillance module of claim 7, wherein the video capturing device further comprises:
a lens set electrically connected to the video-capturing control board for capturing an image.

9. The video surveillance module of claim 1, wherein the motherboard device comprises:
a motherboard;
a thermal conductive sheet disposed on the motherboard; and
a heating device disposed on the thermal conductive sheet for heating the thermal conductive sheet.

10. The video surveillance module of claim 9 further comprising:
a second fan disposed above the heating device for generating a second airflow, the second fan guiding the second airflow to pass through the thermal conductive sheet and the motherboard.
